(19) United States
(12) Patent Application Publication
(10) Pub. No.: US 2026/0007011 A1
(43) Pub. Date: Jan. 1, 2026

(54) DISPLAY PANEL AND DISPLAY DEVICE

(71) Applicant: Xiamen Tianma Display Technology Co., Ltd., Xiamen (CN)

(72) Inventor: Qi XIAO, Xiamen (CN)

(21) Appl. No.: 18/937,574

(22) Filed: Nov. 5, 2024

(30) Foreign Application Priority Data
Jun. 28, 2024 (CN) 202410866896.5

(51) Int. Cl. H10K 59/131; H10K 59/121; H10K 59/123

(52) U.S. Cl. CPC H10K 59/131; H10K 59/1213; H10K 59/123

(57) ABSTRACT

A display panel includes: a substrate, pixel columns arranged along a first direction, a first data line and a second data line extending along the first direction, and signal lines extending along a second direction. One pixel column includes pixel circuits arranged along the second direction. In one pixel column, a portion of pixel circuits is electrically connected to the first data line and another portion is electrically connected to the second data line. A first connection portion is provided on a side of the first data line facing the second data line, and a second connection portion is provided on a side of the second data line facing the first data line. An orthographic projection of at least one of the first connection portion and the second connection portion on the substrate does not overlap orthographic projections of the signal lines.

### CROSS-REFERENCE TO RELATED APPLICATION

This application claims the priority of Chinese Patent Application No. 202410866896.5, filed on Jun. 28, 2024, the content of which is incorporated herein by reference in its entirety.

### TECHNICAL FIELD

The present disclosure generally relates to the field of display technology and, more particularly, relates to a display panel and a display device.

### BACKGROUND

With the continuous development of display technology, refresh rates of display panels are increasing. Under a high refresh rate, a row scanning time of pixel circuits in the display panel is shortened, and a threshold compensation time of the pixel circuits is also shortened accordingly.

To increase the threshold compensation time of the pixel circuits, a dual data line driving method is adopted. That is, multiple pixel circuits in a same pixel column are electrically connected to different data lines. However, under this setting method, crosstalk between the data lines and other signal lines of the display panel is more serious, which is prone to poor display problems.

### SUMMARY

One aspect of the present disclosure provides a display panel. The display panel includes: a substrate; pixel columns, a first data line, a second data line, and signal lines. The pixel columns are arranged along a first direction. One pixel column includes pixel circuits arranged along a second direction, and the first direction intersects the second direction. The first data line and the second data line extend along the second direction. In one pixel column, a portion of pixel circuits is electrically connected to the first data line and another portion is electrically connected to the second data line. A first connection portion is provided on a side of the first data line facing the second data line, and a second connection portion is provided on a side of the second data line facing the first data line. The signal lines all extend along the first direction. Orthographic projections of the signal lines on the substrate are first orthographic projections, orthographic projections of the first connection portion and the second connection portion on the substrate are second orthographic projections, and the second orthographic projection of at least one of the first connection portion and the second connection portion does not overlap with the first orthographic projections of the signal lines.

Another aspect of the present disclosure provides a display device. The display device includes a display panel. The display panel includes: a substrate; pixel columns, a first data line, a second data line, and signal lines. The pixel columns are arranged along a first direction. One pixel column includes pixel circuits arranged along a second direction, and the first direction intersects the second direction. The first data line and the second data line extend along the second direction. In one pixel column, a portion of pixel circuits is electrically connected to the first data line and another portion is electrically connected to the second data line. A first connection portion is provided on a side of the first data line facing the second data line, and a second connection portion is provided on a side of the second data line facing the first data line. The signal lines all extend along the first direction. Orthographic projections of the signal lines on the substrate are first orthographic projections, orthographic projections of the first connection portion and the second connection portion on the substrate are second orthographic projections, and the second orthographic projection of at least one of the first connection portion and the second connection portion does not overlap with the first orthographic projections of the signal lines.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a top view of an exemplary array substrate consistent with various disclosed embodiments in the present disclosure.

FIG. 2 illustrates a top view of another exemplary array substrate consistent with various disclosed embodiments in the present disclosure.

FIG. 3 illustrates a top view of another exemplary array substrate consistent with various disclosed embodiments in the present disclosure.

FIG. 4 illustrates a top view of another exemplary array substrate consistent with various disclosed embodiments in the present disclosure.

FIG. 5 illustrates a top view of another exemplary array substrate consistent with various disclosed embodiments in the present disclosure.

FIG. 6 illustrates equivalent circuit diagrams of a pixel circuit, signal lines, and a light-emitting unit consistent with various disclosed embodiments in the present disclosure.

FIG. 7 illustrates a top view of a semiconductor layer consistent with various disclosed embodiments in the present disclosure.

FIG. 8 illustrates an enlarged view of a portion of FIG. 7 consistent with various disclosed embodiments in the present disclosure.

FIG. 9 illustrates a top view of a first conductive layer consistent with various disclosed embodiments in the present disclosure.

FIG. 10 illustrates a top view of a second conductive layer consistent with various disclosed embodiments in the present disclosure.

FIG. 11 illustrates a top view of a third conductive layer consistent with various disclosed embodiments in the present disclosure.

FIG. 12 illustrates a top view of a fourth conductive layer consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted. Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, terms such as “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc., indicate orientations or positional relationships based on the orientations or positional relationships shown in the accompanying drawings, and are only for the convenience of describing the present disclosure and simplifying the description, and do not indicate or imply that the device or element referred to must have a specific orientation, be constructed and operated in a specific orientation, and therefore should not be understood as limiting the present disclosure.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In the present disclosure, unless otherwise clearly specified and limited, the terms “installed”, “connected”, “fixed” and the like appear, should be understood in a broad sense. For example, it can be a fixed connection, a detachable connection, or an integrated connection; it can be a mechanical connection or an electrical connection; it can be a direct connection or an indirect connection through an intermediate medium, it can be the internal connection of two elements or the interaction relationship between two elements, unless otherwise clearly defined. For those skilled in the art, the specific meanings of the above terms in the present disclosure can be understood according to the specific circumstances.

In the present disclosure, when an element is referred to as being “fixed to” or “disposed on” another element, it may be directly on the other element or there may be an intermediate element. When an element is considered to be “connected to” another element, it may be directly connected to the other element or there may be an intermediate element at the same time. If present, the terms “vertical”, “horizontal”, “upper”, “lower”, “left”, “right” and similar expressions are for illustrative purposes only and are not intended to be the only embodiment.

In a display panel, multiple pixel circuits in a same pixel column are electrically connected to two data lines, and the two data lines includes a first data line and a second data line. The first data line is electrically connected to the pixel circuits of odd rows, and the second data line is electrically connected to the pixel circuits of even rows. The first data line and the second data line corresponding to the pixel columns of two adjacent columns are electrically connected to a chip (such as a ramless IC) through a data transmission line, thereby reducing the number of data transmission lines on the chip to reduce the cost of the chip.

However, since the same pixel column adopts a double data line design, the number of data lines is large, such that the overlapping area between the data lines and other signal lines along the thickness direction of the display panel is large, and the coupling capacitance between the data lines and other signal lines is large. Therefore, the crosstalk between the data lines and other signal lines is more serious. Further, the coupling capacitance between the data lines and a high-level signal line (PVDD) is relatively large. When data is written to one of the data lines corresponding to two adjacent pixel columns through a data transmission line, the other three data lines corresponding to the two adjacent pixel columns are all in a floating state, making the other three data lines susceptible to the influence of other signal lines in the display panel and causing jumps, thereby causing the high-level signal line (PVDD) to jump and couple the floating data, which can easily lead to poor display problems.

The present disclosure provides a display panel and a display device to at least partially alleviate the above problems. The display panel may include a substrate and a plurality of pixel columns located on one side of the substrate. The plurality of pixel columns may be arranged along a first direction, and one pixel column of the plurality of pixel columns may include a plurality of pixel circuits arranged along a second direction, where the first direction intersects with the second direction. The display panel may also include a first data line and a second data line. The first data line and the second data line may extend along the second direction. A portion of the plurality of pixel circuits in one pixel column may be electrically connected to the first data line, and another portion of the plurality of pixel circuits in the pixel column may be electrically connected to the second data line. A first connection portion may be provided on a side of the first data line facing the second data line, and a second connection portion may be provided on a side of the second data line facing the first data line. The display panel may also include a plurality of signal lines. The plurality of signal lines may all extend along the first direction. An orthographic projection of the plurality of signal lines on the substrate may be a first orthographic projection, and an orthographic projection of the first connection portion and the second connection portion on the substrate may be a second orthographic projection. By making the second orthographic projection of at least one of the first connection portion and the second connection portion not overlap with the first orthographic projection of the plurality of signal lines, at least one of the first connection portion and the second connection portion may be made not to overlap with the plurality of signal lines along the thickness direction of the substrate, such that at least one of the first connection portion and the second connection portion avoids the plurality of signal lines to reduce the coupling capacitance between at least one of the first data line and the second data line and each signal line. Therefore, jump amount of at least one of the first data line and the second data line caused by each signal line may be reduced, improving the crosstalk between at least one of the first data line and the second data line and each signal line. Also, the jump amount of the high-level signal line caused by at least one of the first data line and the second data line may be improved, thereby improving the problem of poor display.

The present disclosure also provides a display device. The display device may include any display panel provided by the present disclosure, and may have same beneficial effects of the display panel provided by the present disclosure.

The display device may be a mobile phone or any electronic product with a display function, including but not limited to: televisions, laptops, desktop displays, tablet computers, digital cameras, smart bracelets, smart glasses, car displays, industrial control equipment, medical display screens, touch interactive terminals, etc. The present application does not specifically limit this.

The display panel may include an organic light emitting diode display panel (OLED), a quantum dot electroluminescent display panel (QLED), a mini light emitting diode display (Mini LED), or a micro light emitting diode display (Micro LED). In the following, the display panel as an OLED display panel will be used as an example to illustrate the present disclosure, and does not limit the scope of the present disclosure.

One embodiment of the present disclosure provides a display panel. The display panel may include an array substrate 100 and light-emitting units on one side of the array substrate 100. The array substrate 100 may be electrically connected to the light-emitting units. There may be multiple light-emitting units. For example, the multiple light-emitting units may be arranged in an array. The multiple light-emitting units may include, but are not limited to, red light-emitting units, green light-emitting units, and blue light-emitting units. In some other embodiments, the multiple light-emitting units may also include white light-emitting units.

In one embodiment, exemplarily, one light-emitting unit may include a first electrode, a light-emitting material layer, and a second electrode sequentially arranged away from the array substrate 100. One of the first electrode and the second electrode may be an anode, and the other of the first electrode and the second electrode may be a cathode. The embodiment with the first electrode as an anode and the second electrode as a cathode is used as an example to illustrate the present disclosure, and does not limit the scope of the present disclosure.

Exemplarily, the light-emitting unit may also include one or more of a hole injection layer (HIL), a hole transport layer (HTL), an electron injection layer (EIL), an electron transport layer (ETL), a hole blocking layer (HBL), or an electron blocking layer (EBL).

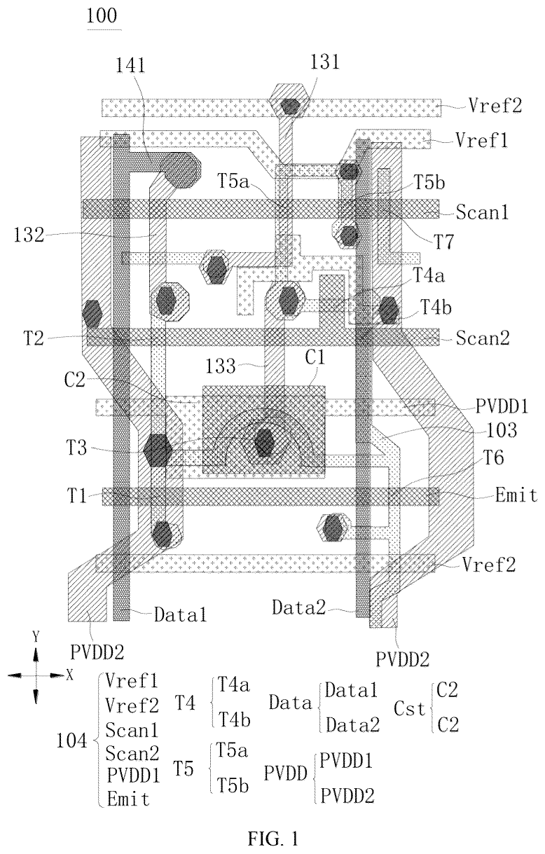

In one embodiment shown in FIG. 1, the array substrate 100 may have a first direction X, a second direction Y and a third direction. The first direction X, the second direction Y and the third direction may all be different. The first direction X and the second direction Y may be any two different directions parallel to the array substrate 100, and the third direction may be any direction intersecting with a plane parallel to the array substrate 100. For example, the first direction X, the second direction Y and the third direction may be perpendicular to each other. Exemplarily, in one embodiment, the first direction X may be the width direction of the array substrate 100, the second direction Y may be the length direction of the array substrate 100, and the third direction may be the thickness direction of the array substrate 100. The length, width and thickness in the embodiments of the present disclosure are only for the convenience of description and do not mean any limitation on the size. For example, the width may be greater than, equal to or less than the length. The direction of the array substrate 100 and the direction of the display panel and the substrate may be the same.

In some embodiments, the array substrate 100 may include a substrate. The substrate may provide support for the remaining film layers that are subsequently arranged.

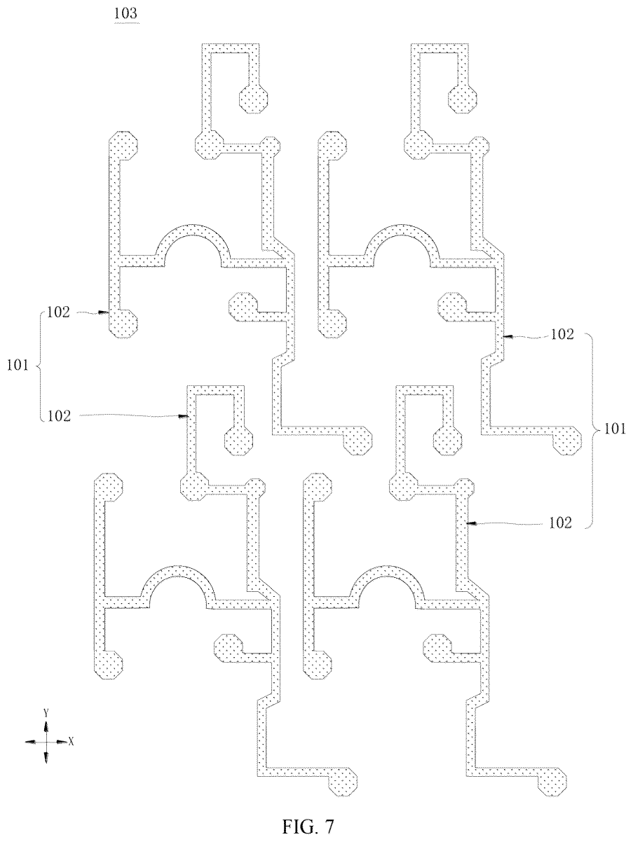

FIG. 7 shows a schematic diagram of the structure of the semiconductor layer 103 corresponding to two pixel columns 101. As shown in FIG. 7, the array substrate 100 may include a plurality of pixel columns 101 on the substrate, and the plurality of pixel columns 101 may be arranged along the first direction X. Each pixel column 101 may include a plurality of pixel circuits 102 arranged along the second direction Y. One pixel circuit 102 may be electrically connected to one corresponding light-emitting unit to provide a driving signal to the corresponding light-emitting unit. One pixel circuit 102 may include a plurality of transistors (Thin Film Transistors, TFTs) and a storage capacitor Cst.

In one embodiment, exemplarily, the plurality of pixel circuits 102 on the array substrate 100 may be arranged in an array of multiple rows and columns along the first direction X and the second direction Y. The embodiment with the first direction X as the row direction and the second direction Y as the column direction is used as an example only to illustrate the present disclosure.

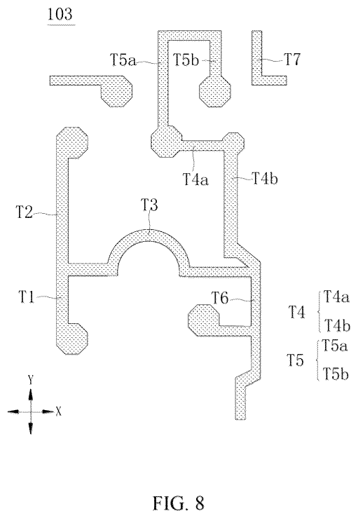

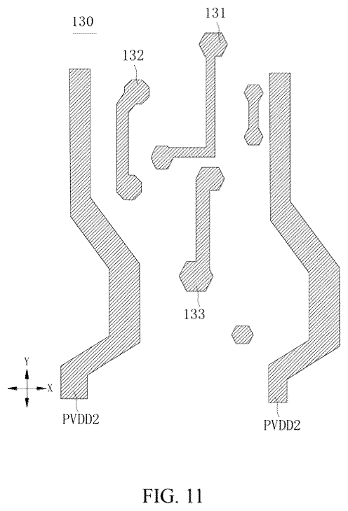

As shown in FIG. 7, FIG. 8, and FIG. 11, one pixel circuit 102 may include a plurality of transistors, and the plurality of transistors may include any one or more of a first write transistor T2, a second write transistor T4, a first light-emitting transistor T1, a second light-emitting transistor T6, an anode reset transistor T7, a gate reset transistor T5, and a driving transistor T3. The first write transistor T2, the second write transistor T4, the first light-emitting transistor T1, the second light-emitting transistor T6, the anode reset transistor T7, and the gate reset transistor T5 may be switch transistors. One switch transistor may mainly function as a switch. The driving transistor T3 may drive the corresponding light-emitting unit connected to the pixel circuit 102 to emit light.

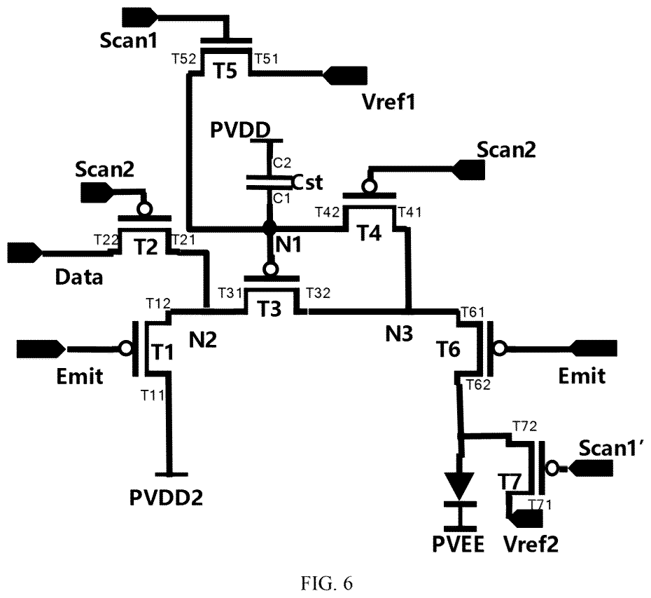

As shown in FIG. 1 and FIG. 6, a second electrode T22 of the first write transistor T2 may be electrically connected to one data line Data of the first data line Data1 or the second data line Data2, and a first electrode T21 of the first write transistor T2 may be electrically connected to a first electrode T31 of the driving transistor T3. A second electrode T32 of the driving transistor T3 may be electrically connected to a first electrode T41 of the second write transistor T4, and a second electrode T42 of the second write transistor T4 may be electrically connected to a gate electrode of the driving transistor T3 and a first electrode C1 of the storage capacitor Cst. A first electrode T11 of the first light-emitting transistor T1 may be electrically connected to one power signal line PVDD of the first power signal line PVDD1 and/or the second power signal line PVDD2, and a second electrode T12 of the first light-emitting transistor T1 may be electrically connected to a first electrode T31 of the driving transistor T3. A first electrode T61 of the second light-emitting transistor T6 may be electrically connected to a second electrode T32 of the driving transistor T3, and a second electrode T62 of the second light-emitting transistor T6 may be electrically connected to the anode. A first electrode T71 of the anode reset transistor T7 may be electrically connected to a second reference signal line Vref2, and a second electrode T72 of the anode reset transistor T7 may be electrically connected to the anode. A first electrode T51 of the gate reset transistor T5 may be electrically connected to the first reference signal line Vref1, and a second electrode T52 of the gate reset transistor T5 may be electrically connected to a gate of the driving transistor T3 and a first electrode C1 of the storage capacitor Cst. A second electrode C2 of the storage capacitor Cst may be electrically connected to one power signal line PVDD (the first power signal line PVDD1 and/or the second power signal line PVDD2). A third power signal line PVEE may be electrically connected to the cathode. The gate of the first write transistor T2 and the gate of the second write transistor T4 may both be connected to the second scan signal line Scan2. The gate of the first light-emitting transistor T1 and the gate of the second light-emitting transistor T6 may both be connected to the light-emitting control signal line Emit. The gate of the anode reset transistor T7 may be electrically connected to the first scan signal line Scan1′ corresponding to the pixel circuits 102 of the next row, and the gate of the gate reset transistor T5 may be electrically connected to the first scan signal line Scan1 corresponding to the pixel circuits 102 of the current row. The gate of the driving transistor T3 may be connected to the first electrode C1 of the storage capacitor Cst.

In one embodiment, the gate of the driving transistor T3 may be reused as the first electrode C1 of the storage capacitor Cst, thereby simplifying the structure of the array substrate 100 and reducing the manufacturing cost.

As shown in FIG. 1 and FIG. 6, in one embodiment, the first power signal line PVDD1 and a second power signal line PVDD2 may be provided at the same time, and the first power signal line PVDD1 and the second power signal line PVDD2 may be electrically connected. The second power signal line PVDD2 may be electrically connected to the first light-emitting transistor T1, to realize that the power signal line PVDD is electrically connected to the first electrode T11 of the first light-emitting transistor.

It should be noted that, in one transistor, one of the first electrode and the second electrode of the transistor may be the source of the transistor, and the other of the first electrode and the second electrode of the transistor may be the drain of the transistor.

In some embodiments, each of any one or more of the above-mentioned plurality of transistors (T1-T7) may include two electrically connected sub-transistors to reduce the leakage current of the transistor. For example, the second write transistor T4 and/or the gate reset transistor T5 may include two sub-transistors respectively. In one embodiment shown in FIG. 1, the second write transistor T4 may include two sub-transistors, that is, a first sub-write transistor T4a and a second sub-write transistor T4b electrically connected. For another example, as shown in FIG. 1, the gate reset transistor T5 may include two sub-transistors, that is, a first sub-gate reset transistor T5a and a second sub-gate reset transistor T5b that are electrically connected.

In one embodiment, exemplarily, the types of the plurality of transistors in the pixel circuit 102 may all be P-type transistors or N-type transistors. In some other embodiments, a portion of the plurality of transistors may be P-type transistors, and a remaining portion of the plurality of transistors may be N-type transistors. Different enable levels may be provided according to different transistor types. The enable level refers to the level that turns on the transistor. Exemplarily, when one transistor is a P-type transistor, the enable level may be a low level, and, when the transistor is an N-type transistor, the enable level may be a high level. The embodiment where the plurality of transistors are P-type transistors is used as an example only to illustrate the present disclosure, and does not limit the scope of the present disclosure.

In one embodiment shown in FIG. 1, the array substrate 100 may include data lines Data extending along a second direction Y. The data lines Data may be electrically connected to corresponding pixel columns 101. In one pixel column 101 and the correspondingly arranged data lines Data, the data lines Data may include a first data line Data1 and a second data line Data2, both of which extend along the second direction Y. A portion of the pixel circuits 102 in the pixel column 101 may be electrically connected to the first data line Data1, and another portion of the pixel circuits 102 may be electrically connected to the second data line Data2.

In one embodiment, in two adjacent pixel circuits 102 in the second direction Y, the first data line Data1 may be electrically connected to the second electrode T22 of the first write transistor T2 of one of the pixel circuits 102, and the second data line Data2 may be electrically connected to the second electrode T22 of the first write transistor T2 of the other pixel circuit 102. For example, one of the first data line Data1 and the second data line Data2 may be electrically connected to the pixel circuit 102 in the corresponding pixel column 101 of an odd-numbered row, and the other of the first data line Data1 and the second data line Data2 may be electrically connected to the pixel circuit 102 in the corresponding pixel column 101 of an even-numbered row. Since the first data line Data1 and the second data line Data2 are correspondingly arranged with each pixel column 101, the data writing time may be increased, which is beneficial to high refresh and power consumption.

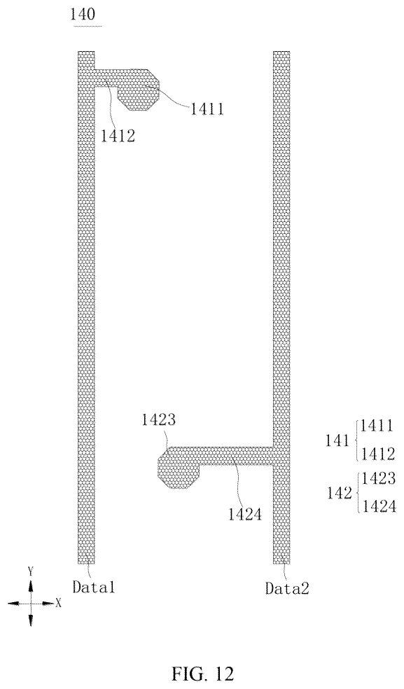

For example, in one embodiment, the first data line Data1 and the second data line Data2 may both be formed by the fourth conductive layer 140 (FIG. 12), which is beneficial to the simultaneous preparation of the first data line Data1 and the second data line Data2, thereby simplifying the preparation process of the first data line Data1 and the second data line Data2.

In some embodiments, as shown in FIG. 1, the array substrate 100 may include a plurality of signal lines 104. The plurality of signal lines 104 may all extend along the first direction X, and the plurality of signal lines 104 may include at least one of a first scan signal line Scan1, a second scan signal line Scan2, a light emitting control signal line Emit, a first reference signal line Vref1, a second reference signal line Vref2, or a first power signal line PVDD1. Multiple pixel circuits 102 arranged along the first direction X may form a row of pixel circuits (i.e., a pixel row), and a plurality of signal lines 104 may be correspondingly provided to one pixel row.

Exemplarily, in one embodiment, as shown in FIG. 1 and FIG. 12, a first connection portion 141 may be provided on a side of the first data line Data1 facing the second data line Data2, and a second connection portion 142 may be provided on a side of the second data line Data2 facing the first data line Data1. The orthographic projection of the plurality of signal lines 104 on the substrate may be the first orthographic projection, the orthographic projection of the first connection portion 141 and the second connection portion 142 on the substrate may be the second orthographic projection, and the second orthographic projection of at least one of the first connection portion 141 and the second connection portion 142 may not overlap with the first orthographic projection of the plurality of signal lines 104. With such a configuration, at least one of the first connection portion 141 or the second connection portion 142 may be made not to overlap with the plurality of signal lines 104 along the thickness direction of the substrate, such that at least one of the first connection portion 141 and the second connection portion 142 avoids the plurality of signal lines 104 to reduce the coupling capacitance between at least one of the first data line Data1 and the second data line Data2 and each signal line 104. Therefore, the jump amount of at least one of the first data line Data1 and the second data line Data2 caused by each signal line 104 may be reduced, and the crosstalk between at least one of the first data line Data1 and the second data line Data2 and each signal line 104 may be improved. Further, the jump amount of the high-level signal line 104 caused by at least one of the first data line Data1 and the second data line Data2 may also be improved, thereby improving the problem of poor display.

Exemplarily, in one embodiment, in two adjacent pixel circuits 102 in the second direction Y, the first data line Data1 may be electrically connected to the second electrode T22 of the first write transistor T2 of one of the pixel circuits 102 through the first connection portion 141, and the second data line Data2 may be electrically connected to the second electrode T22 of the first write transistor T2 of the other pixel circuit 102 through the second connection portion 142. For example, one of the first connection portion 141 and the second connection portion 142 may be electrically connected to the pixel circuits 102 of the odd-numbered row, and the other of the first connection portion 141 and the second connection portion 142 may be electrically connected to the pixel circuits 102 of the even-numbered row.

For example, in one embodiment, the first connection portion 141 may be arranged corresponding to the pixel circuits 102 of the odd row, and the second connection portion 142 may be arranged corresponding to the pixel circuits 102 of the even row. The plurality of signal lines 104 arranged corresponding to the pixel circuits 102 of the odd row may not overlap with the first connection portion 141 along the thickness direction of the substrate. The plurality of signal lines 104 arranged corresponding to the pixel circuits 102 of the even row may not overlap with the second connection portion 142 along the thickness direction of the substrate. The positional relationship between the first connection portion 141 and the corresponding plurality of signal lines 104 may be the same as or different from the positional relationship between the second connection portion 142 and the corresponding plurality of signal lines 104.

In one embodiment shown in FIG. 1 and FIG. 12, the plurality of signal lines 104 may be arranged at intervals along the second direction Y, and the second orthographic projection of at least one of the first connection portion 141 and the second connection portion 142 may be located between two adjacent first orthographic projections of the corresponding plurality of signal lines 104, such that the area between the two adjacent first orthographic projections is used to set the corresponding first connection portion 141 and the second connection portion 142. Therefore, a compact layout may be achieved.

Exemplarily, the two adjacent signal lines 104 may include a first signal line and a second signal line, and the second orthographic projection of at least one of the first connection portion 141 and the second connection portion 142 may be located between the first orthographic projection of the corresponding first signal line and the first orthographic projection of the corresponding second signal line. The distance between the second orthographic projection of the first connection portion 141 and the first orthographic projection of the corresponding first signal line along the second direction Y may be equal to or not equal to the distance between the second orthographic projection of the first connection portion 141 and the first orthographic projection of the corresponding second signal line along the second direction Y, such that the setting position of the first connection portion 141 relative to the corresponding first signal line and the second signal line may be more flexible. The distance between the second orthographic projection of the second connection portion 142 and the first orthographic projection of the corresponding first signal line along the second direction Y may be equal to or not equal to the distance between the second orthographic projection of the second connection portion 142 and the first orthographic projection of the corresponding second signal line along the second direction Y, such that the second connection portion 142 may be more flexible in setting the position relative to the corresponding first signal line and the second signal line.

In some embodiments, as shown in FIG. 1, the first orthographic projection of the first reference signal line Vref1 may be located on one side of the first orthographic projection of the first scan signal line Scan1 along the second direction Y. The first orthographic projection of the second scan signal line Scan2 may be located on a side of the first orthographic projection of the first scan signal line Scan1 away from the first orthographic projection of the first reference signal line Vref1. The first orthographic projection of the first power signal line PVDD1 may be located on a side of the first orthographic projection of the second scan signal line Scan2 away from the first orthographic projection of the first scan signal line Scan1. The first orthographic projection of the light emitting control signal line Emit may be located on a side of the first orthographic projection of the first power signal line PVDD1 away from the first orthographic projection of the second scan signal line Scan2. The first orthographic projection of the second reference signal line Vref2 may be located on a side of the first orthographic projection of the light emitting control signal line Emit away from the first orthographic projection of the first power signal line PVDD1.

In some examples, as shown in FIG. 1 and FIG. 12, the second orthographic projection of at least one of the first connection portion 141 and the second connection portion 142 may be located between the first orthographic projection of the corresponding first scan signal line Scan1 and the first orthographic projection of the first reference signal line Vref1, such that at least one of the first connection portion 141 and the second connection portion 142 does not overlap with the first scan signal line Scan1 and the first reference signal line Vref1 along the thickness direction of the substrate, thereby improving the crosstalk between at least one of the first data line Data1 and the second data line Data2 and the first scan signal line Scan1 and the first reference signal line Vref1. Further, the jump amount of the high-level signal line 104 caused by at least one of the first data line Data1 and the second data line Data2 may also be improved, thereby improving the problem of poor display.

For example, the first reference signal line Vref1 may be moved in a direction away from the first scan signal line Scan1, and/or the first scan signal line Scan1 may be moved in a direction away from the first reference signal line Vref1, to increase the distance between the first orthographic projection of the first scan signal line Scan1 and the first orthographic projection of the first reference signal line Vref1, such that at least one of the first connection portion 141 and the second connection portion 142 does not overlap with the corresponding first scan signal line Scan1 and the first reference signal line Vref1 along the thickness direction of the substrate.

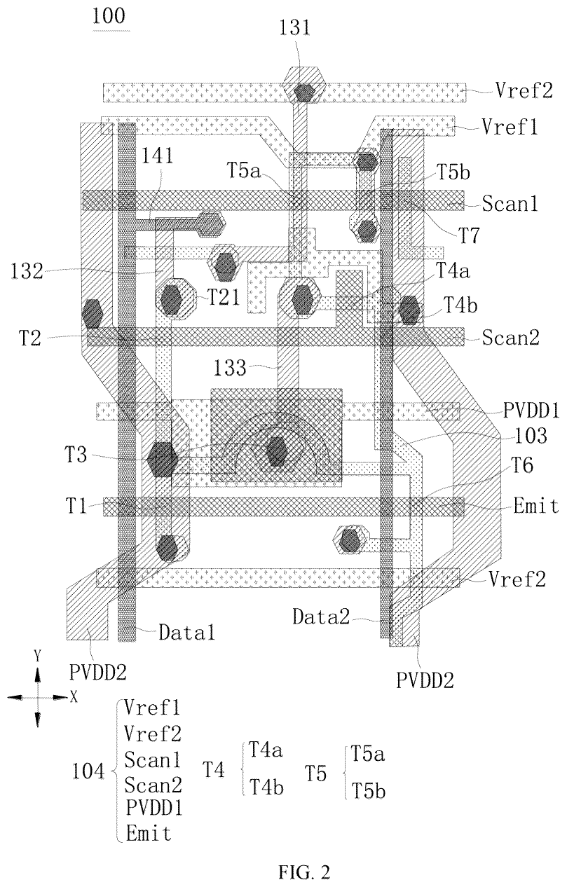

In other examples, as shown in FIG. 2 and FIG. 12, the second orthographic projection of at least one of the first connection portion 141 and the second connection portion 142 may be located between the corresponding first scan signal line Scan1 and the second scan signal line Scan2, such that at least one of the first connection portion 141 and the second connection portion 142 and the first scan signal line Scan1 and the second scan signal line Scan2 does not overlap along the thickness direction of the substrate, thereby improving the crosstalk between at least one of the first data line Data1 and the second data line Data2 and the first scan signal line Scan1 and the second scan signal line Scan2. Further, the jump amount of the high-level signal line 104 caused by at least one of the first data line Data1 and the second data line Data2 may also be improved, thereby improving the problem of poor display.

For example, the second electrode T22 of the first write transistor T2 may be set between the first scanning signal line Scan1 and the second scanning signal line Scan2. When the second orthographic projection of at least one of the first connection portion 141 and the second connection portion 142 is located between the corresponding first scanning signal line Scan1 and the second scanning signal line Scan2, it is beneficial to reduce the distance between at least one of the first connection portion 141 and the second connection portion 142 and the second electrode T22 of the corresponding first write transistor T2, thereby helping to reduce the length of the second auxiliary component 132 and reduce the interference between the second auxiliary component 132 and other signal lines 104.

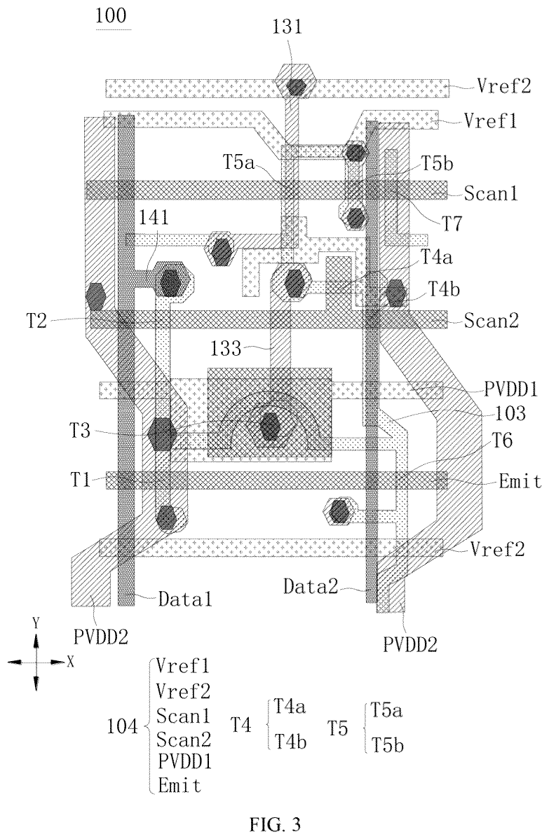

As shown in FIG. 3 and FIG. 12, in some embodiments, the second orthographic projection of at least one of the first connection portion 141 and the second connection portion 142 may cover at least part of the orthographic projection of the second electrode T22 of the corresponding first write transistor T2 on the substrate, and at least one of the first connection portion 141 and the second connection portion 142 may be directly electrically connected to the second electrode T22 of the corresponding first write transistor T2 through a via hole, thereby eliminating the need to provide the second auxiliary member 132 (FIG. 2), to simplify the structure of the array substrate 100 and reduce the difficulty of preparation.

In one embodiment in which the second orthographic projection of the first connection portion 141 is located between the corresponding first scan signal line Scan1 and the second scan signal line Scan2, the second orthographic projection of the first connection portion 141 may have a first distance from the first orthographic projection of the first scan signal line Scan1 along the second direction Y, and the second orthographic projection of the first connection portion 141 may have a second distance from the first orthographic projection of the second scan signal line Scan2 along the second direction Y. The first distance may be smaller than the second distance, and the first connection portion 141 may be disposed closer to the first scan signal line Scan1. Or the first distance is larger than the second distance, and the first connection portion 141 may be disposed closer to the second scan signal line Scan2. Therefore, the first connection portion 141 may be disposed more flexibly relative to the first scan signal line Scan1 and the second scan signal line Scan2.

In one embodiment in which the second orthographic projection of the second connection portion 142 is located between the corresponding first scan signal line Scan1 and the second scan signal line Scan2, the second orthographic projection of the second connection portion 142 may have a third distance from the first orthographic projection of the first scan signal line Scan1 along the second direction Y, and the second orthographic projection of the second connection portion 142 may have a fourth distance from the first orthographic projection of the second scan signal line Scan2 along the second direction Y. The third distance may be smaller than the fourth distance, or the third distance may be larger than the fourth distance, such that the second connection portion 142 is disposed more flexibly relative to the first scan signal line Scan1 and the second scan signal line Scan2.

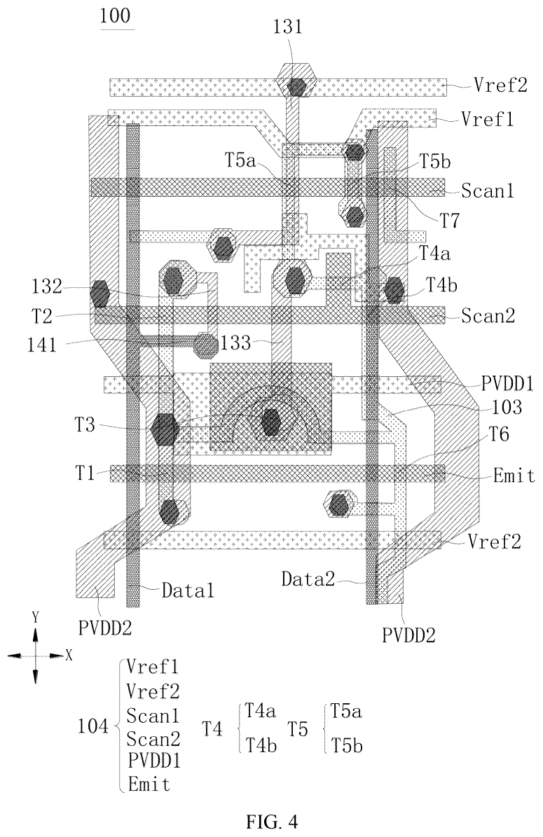

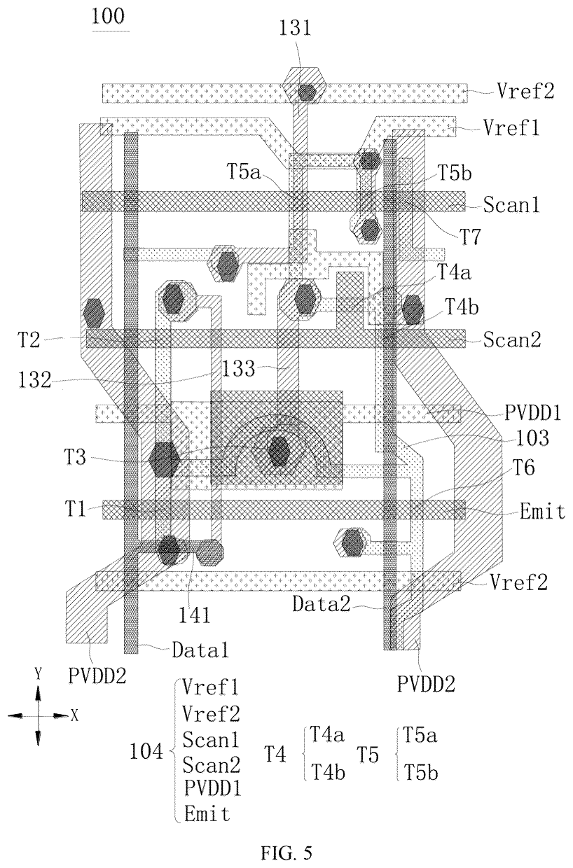

In some other embodiments shown in FIG. 4, FIG. 5 and FIG. 12, the second orthographic projection of at least one of the first connection portion 141 and the second connection portion 142 may be located on the side of the first orthographic projection of the corresponding second scan signal line Scan2 away from the first orthographic projection of the first scan signal line Scan1.

For example, as shown in FIG. 4 and FIG. 12, the second orthographic projection of at least one of the first connection portion 141 and the second connection portion 142 may be located between the corresponding second scan signal line Scan2 and the first power signal line PVDD1, such that at least one of the first connection portion 141 and the second connection portion 142 and the second scan signal line Scan2 and the first power signal line PVDD1 do not overlap along the thickness direction of the substrate, and the crosstalk between at least one of the first data line Data1 and the second data line Data2 and the second scan signal line Scan2 and the first power signal line PVDD1 may be improved. Further, the jump amount of the high-level signal line 104 caused by at least one of the first data line Data1 and the second data line Data2 may also be improved, thereby improving the problem of poor display.

For another example, as shown in FIG. 5 and FIG. 12, the second orthographic projection of at least one of the first connection portion 141 and the second connection portion 142 may be located between the corresponding second reference signal line Vref2 and the light-emitting control signal line Emit, such that at least one of the first connection portion 141 and the second connection portion 142 and the second reference signal line Vref2 and the light-emitting control signal line Emit do not overlap along the thickness direction of the substrate, thereby improving the crosstalk between at least one of the first data line Data1 and the second data line Data2 and the second reference signal line Vref2 and the light-emitting control signal line Emit. In addition, the jump amount of the high-level signal line 104 caused by at least one of the first data line Data1 and the second data line Data2 may also be improved, thereby improving the problem of poor display.

In one embodiment, the distance between the first orthographic projection and the second orthographic projection along the second direction Y may be larger than or equal to 1 μm, such that the distance between the first orthographic projection and the second orthographic projection along the second direction Y is larger to significantly reduce the coupling capacitance between the first data line Data1, the second data line Data2 and each signal line 104, thereby better reducing the jump amount of the first data line Data1 and the second data line Data2 caused by each signal line 104, and better improve the crosstalk between the first data line Data1 and the second data line Data2 and each signal line 104. In addition, the jump amount of the high-level signal line 104 caused by the first data line Data1 and the second data line Data2 may also be better improved, thereby better improving the problem of poor display. For example, the distance between the first orthographic projection and the second orthographic projection along the second direction Y may be 1 μm, 1.5 μm, 2 μm, 2.5 μm or any value greater than 1 μm.

Exemplarily, the size of at least one of the first data line Data1 and the second data line Data2 along the first direction X may be less than or equal to 2.5 μm, such that the size of at least one of the first data line Data1 and the second data line Data2 along the first direction X is small, which is conducive to reducing the influence of at least one of the first data line Data1 and the second data line Data2 on the layout of other conductive structures. In addition, it may be also conducive to reducing the overlapping area between at least one of the first data line Data1 and the second data line Data2 and the second power signal line PVDD2 and each signal line 104 along the substrate thickness direction, thereby reducing the coupling capacitance between at least one of the first data line Data1 and the second data line Data2 and the second power signal line PVDD2 and each signal line 104, improving the jump amount of the high-level signal line 104 caused by the first data line Data1 and the second data line Data2, and improving display defects. For example, the size of at least one of the first data line Data1 and the second data line Data2 along the first direction X may be 1.5 μm, 1.8 μm, 2 μm, 2.3 μm, 2.5 μm or any value less than 2.5 μm.

In one embodiment shown in FIG. 12, the first connection portion 141 may include a first sub-connection portion 1411 and a second sub-connection portion 1412. The first sub-connection portion 1411 may be located on a side of the second sub-connection portion 1412 away from the first data line Data1. The first sub-connection portion 1411 may be electrically connected to the corresponding pixel circuit 102 through the first via hole. The size of the first sub-connection portion 1411 along the second direction Y may be larger than the size of the second sub-connection portion 1412 along the second direction Y, such that the size of the first sub-connection portion 1411 along the second direction Y is larger, which is conducive to reducing the connection difficulty between the first sub-connection portion 1411 and the first via hole. In addition, the size of the second sub-connection portion 1412 along the second direction Y may be smaller, which is conducive to increasing the distance between the second sub-connection portion 1412 and each signal line 104 along the second direction Y, thereby facilitating improvement of the crosstalk between the first data line Data1 and each signal line 104. In addition, it may be also conducive to improving the jump amount of the high-level signal line 104 caused by the first data line Data1. The principle has been explained and will not be repeated.

Exemplarily, the size of the first sub-connection portion 1411 along the second direction Y may be less than or equal to 8 μm, such that the size of the first sub-connection portion 1411 along the second direction Y is prevented from being too large, which is beneficial to reducing the impact of the first sub-connection portion 1411 on the layout of other conductive structures and improving the crosstalk between the first data line Data1 and each signal line 104. For example, the size of the first sub-connection portion 1411 along the second direction Y may be 3 μm, 4 μm, 5 μm, 6 μm, 7 μm, 8 μm, or any value less than 8 μm.

Exemplarily, the size of the second sub-connection portion 1412 along the second direction Y may be less than or equal to 2.5 μm, such that the size of the second sub-connection portion 1412 along the second direction Y is small, which is beneficial to reduce the impact of the second sub-connection portion 1412 on the layout of other conductive structures and improve the crosstalk between the first data line Data1 and each signal line 104. For example, the size of the second sub-connection portion 1412 along the second direction Y may be 1.5 μm, 1.8 μm, 2 μm, 2.3 μm, 2.5 μm or any value less than 2.5 μm.

In one embodiment shown in FIG. 12, the second connection portion 142 may include a third sub-connection portion 1423 and a fourth sub-connection portion 1424. The third sub-connection portion 1423 may be located on the side of the fourth sub-connection portion 1424 away from the second data line Data2. The third sub-connection portion 1423 may be electrically connected to the corresponding pixel circuit 102 through the second via hole. The size of the third sub-connection portion 1423 along the second direction Y may be larger than the size of the fourth sub-connection portion 1424 along the second direction Y, thereby reducing the difficulty of connection between the third sub-connection portion 1423 and the second via hole. Further, it may be also beneficial to improve the crosstalk between the second data line Data2 and each signal line 104, and its principle is similar to that of the first connection portion 141, which will not be repeated.

Exemplarily, the size of the third sub-connection portion 1423 along the second direction Y may be less than or equal to 8 μm, which is beneficial to reduce the layout influence of the third sub-connection portion 1423 on other conductive structures and improve the crosstalk between the second data line Data2 and each signal line 104. For example, the size of the third sub-connection portion 1423 along the second direction Y may be 3 μm, 4 μm, 5 μm, 6 μm, 7 μm, 8 μm or any value less than 8 μm.

Exemplarily, the size of the fourth sub-connection portion 1424 along the second direction Y may be less than or equal to 2.5 μm, which is conducive to reducing the layout influence of the fourth sub-connection portion 1424 on other conductive structures and improving the crosstalk between the second data line Data2 and each signal line 104. For example, the size of the fourth sub-connection portion 1424 along the second direction Y may be 1.5 μm, 1.8 μm, 2 μm, 2.3 μm, 2.5 μm or any value less than 2.5 μm.

Exemplarily, the size of the first sub-connection portion 1411 and the first via hole may be reduced such that the first connection portion 141 and each signal line 104 do not overlap along the thickness direction of the substrate, to reduce the coupling capacitance between the first data line Data1 and each signal line 104, thereby improving the crosstalk problem. Similarly, the size of the fourth sub-connection portion 1424 and the second via hole may be reduced so that the fourth sub-connection portion 1424 and the signal lines 104 do not overlap along the thickness direction of the substrate, thereby reducing the coupling capacitance between the second data line Data2 and the signal lines 104 and improving the crosstalk problem.

The following is a description of the film layers arranged along the thickness direction of the array substrate 100 provided by the present disclosure.

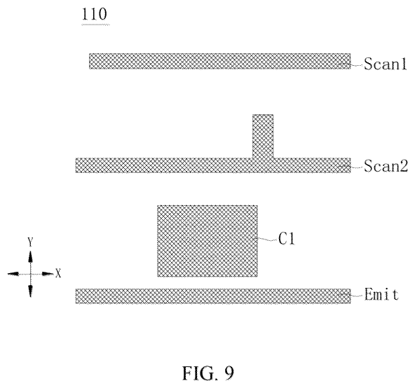

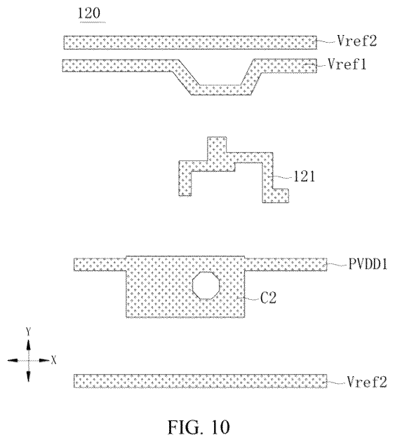

Along the thickness direction of the substrate, the array substrate 100 may include a semiconductor layer 103 (FIG. 8), a first conductive layer 110 (FIG. 9), a second conductive layer 120 (FIG. 10), a third conductive layer 130 (FIG. 11) and a fourth conductive layer 140 (FIG. 12) stacked sequentially on the substrate. An insulating layer may be provided between each adjacent two of the semiconductor layer 103, the first conductive layer 110, the second conductive layer 120, the third conductive layer 130 and the fourth conductive layer 140. The materials of any two insulating layers may be the same or different.

Exemplarily, as shown in FIG. 8, the semiconductor layer 103 may include active layers of the plurality of transistors (T1-T7).

Exemplarily, as shown in FIG. 9, the first conductive layer 110 may include at least one of a first scan signal line Scan1, a second scan signal line Scan2, a first electrode C1 of a storage capacitor Cst, a light emitting control signal line Emit and a gate of a plurality of transistors.

Exemplarily, as shown in FIG. 10, the second conductive layer 120 may include at least one of a first reference signal line Vref1, a second reference signal line Vref2, a first power signal line PVDD1, and a second electrode C2 of a storage capacitor Cst. The first electrode C1 and the second electrode C2 of the storage capacitor Cst may be arranged relative to each other along the thickness direction of the substrate.

As shown in FIG. 10, in one embodiment in which the second conductive layer 120 includes the first power signal line PVDD1 and the second electrode C2 of the storage capacitor Cst, the first power signal line PVDD1 and the second electrode C2 may be an integral structure, thereby facilitating the reduction of the difficulty of preparing the first power signal line PVDD1 and the second electrode C2. For example, the second power signal line PVDD2 may be electrically connected to the second electrode C2 through the first power signal line PVDD1, which may reduce the difficulty of connecting the second power signal line PVDD2 to the second electrode C2.

Exemplarily, as shown in FIG. 11, the third conductive layer 130 may include a second power signal line PVDD2.

Exemplarily, as shown in FIG. 12, the fourth conductive layer 140 may include a first data line Data1 and a second data line Data2.

Exemplarily, at least one of the third conductive layer 130 and the fourth conductive layer 140 may further include a third power signal line PVEE (FIG. 6).

Exemplarily, the power signals provided by the first power signal line PVDD1 and the second power signal line PVDD2 may be the same, and the first power signal line PVDD1 may be used to provide a first power signal to the anode of the light-emitting unit, and the first power signal may be a high-level signal. The first power signal line PVDD1 and the second power signal line PVDD2 may be electrically connected, to reduce the total resistance of the first power signal line PVDD1 and the second power signal line PVDD2 and reduce the voltage drop of the first power signal line PVDD1 and the second power signal line PVDD2, to improve the display effect of the display panel. The array substrate 100 may be provided with at least one of the first power signal line PVDD1 and the second power signal line PVDD2.

Exemplarily, the power signals provided by the first power signal line PVDD1 and the third power signal line PVEE may be different. The third power signal line PVEE may be used to provide a second power signal to the cathode of the light-emitting unit, and the second power signal may be a low-level signal.

In one embodiment shown in FIG. 1, FIG. 6 and FIG. 11, a first auxiliary member 131 may be provided for each pixel circuit 102. For example, the first auxiliary member 131 may be formed by the third conductive layer 130. The second reference signal line Vref2 may be electrically connected to the first electrode T71 of the anode reset transistor through the first auxiliary member 131.

In one embodiment shown in FIG. 1, FIG. 6 and FIG. 11, a second auxiliary member 132 may be provided for each pixel circuit 102. For example, the second auxiliary member 132 may be formed by the third conductive layer 130. The first data line Data1 and/or the second data line Data2 may be electrically connected to the second electrode T22 of the corresponding first write transistor T2 through the second auxiliary member 132.

In one embodiment shown in FIG. 1, FIG. 6 and FIG. 11, a third auxiliary member 133 may be provided for each pixel circuit 102. For example, the third auxiliary member 133 may be formed by the third conductive layer 130. The second electrode T42 of the second write transistor T4 may be electrically connected to the gate of the drive transistor T3 (i.e., the first electrode C1 of the storage capacitor Cst) through the third auxiliary component 133, such that the data line Data charges the gate of the drive transistor T3 (i.e., the first electrode C1 of the storage capacitor Cst) through the corresponding first write transistor T2, the drive transistor T3, the second write transistor T4 and the third auxiliary component 133.

In one embodiment shown in FIG. 1 and FIG. 10, one pixel circuit 102 may be provided with a corresponding shielding component 121, and the shielding component 121 may be formed by the second conductive layer 120. The shielding component 121 may be electrically connected to the second power signal line PVDD2, and the shielding component 121 may shield the data lines Data and the node N1 (FIG. 6), thereby reducing the coupling between the data lines Data and the node N1.

The semiconductor layer 103 may be made of a material including polysilicon (for example, low temperature polysilicon or high temperature polysilicon), metal oxide or amorphous silicon, etc. The materials of any one or more of the first conductive layer 110, the second conductive layer 120, the third conductive layer 130 and the fourth conductive layer 140 may include metals (such as silver, aluminum, copper, etc.) or metal compounds (such as metal nitrides, metal oxides, etc.) When any one of the first conductive layer 110, the second conductive layer 120, the third conductive layer 130 and the fourth conductive layer 140 is electrically connected to the semiconductor layer 103, a via hole may be provided in the insulating layer between the any one of the first conductive layer 110, the second conductive layer 120, the third conductive layer 130 or the fourth conductive layer 140, and the semiconductor layer 103, and a conductive material may be filled in the via hole to achieve electrical connection between the two. When any two of the first conductive layer 110, the second conductive layer 120, the third conductive layer 130 and the fourth conductive layer 140 are electrically connected, a via hole may be provided in the insulating layer between the two, and a conductive material may be filled in the via hole to achieve electrical connection between the two.

The working process of the pixel circuit 102 provided by the present disclosure is described below.

In the first stage (i.e., the reset stage), the light-emitting control signal line Emit may provide a high level to control the first light-emitting transistor T1 and the second light-emitting transistor T6 to be turned off, and the light-emitting unit may not emit light. The second scanning signal line Scan2 may provide a high level to control the first write transistor T2 and the second write transistor T4 to be turned off. The first scanning signal line Scan1 of this row may provide a low level to control the gate reset transistor T5 to be turned on, and the reference voltage of the first reference signal line Vref1 may be transmitted to the gate of the storage drive transistor T3 (i.e., the first electrode C1 of the storage capacitor), the gate of the drive transistor T3 (i.e., the first electrode C1) may be reset. The first scanning signal line Scan1′ of the next row may provide a low level to control the anode reset transistor T7 to be turned on, and the reference voltage of the second reference signal line Vref2 may be transmitted to the anode to reset the anode of the light-emitting unit.

In the second stage (i.e., the write stage), the light-emitting control signal line Emit may provide a high level to control the first light-emitting transistor T1 and the second light-emitting transistor T6 to be turned off, and the light-emitting unit may not emit light. The first scan signal line Scan1 of this row may provide a high level to control the gate reset transistor T5 to be turned off. the first scan signal line Scan1 of the next row may provide a high level to control the anode reset transistor T7 to be turned off. The second scan signal line Scan2 may provide a low level to control the first write transistor T2 and the second write transistor T4 to be turned on. The data voltage of the data lines Data (the first data line Data1 or the second data line Data2) may be transmitted to the first electrode C1 of the storage capacitor Cst through the first write transistor T2, the drive transistor T3 and the second write transistor T4, and the storage capacitor Cst may be charged.

In the third stage (i.e., the light-emitting stage), the first scan signal line Scan1 of this row may provide a high level to control the gate reset transistor T5 to be turned off. The first scan signal line Scan1 of the next row may provide a high level to control the anode reset transistor T7 to be turned off, and the second scan signal line Scan2 may provide a high level to control the first write transistor T2 and the second write transistor T4 to be turned off. The light-emitting control signal line Emit may provide a low level to control the first light-emitting transistor T1 and the second light-emitting transistor T6 to be turned on. Under the potential control of the first electrode C1 of the storage capacitor Cst, the drive transistor T3 may be turned on. The power signal of the power signal line PVDD may be transmitted to the anode through the first light emitting transistor T1, the driving transistor T3 and the second light emitting transistor T6. The power signal line PVDD may provide a driving current to the light emitting unit to drive the light emitting unit to emit light.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising:
a substrate;
a plurality of pixel columns located on one side of the substrate, wherein the plurality of pixel columns is arranged along a first direction, one pixel column of the plurality of pixel columns includes a plurality of pixel circuits arranged along a second direction, and the first direction intersects with the second direction;
a first data line and a second data line, wherein: the first data line and the second data line extend along the second direction, a portion of pixel circuits in one pixel column of the plurality of pixel columns is electrically connected to the first data line and another portion of the pixel circuits in the pixel column is electrically connected to the second data line, a first connection portion is provided on a side of the first data line facing the second data line, and a second connection portion is provided on a side of the second data line facing the first data line; and
a plurality of signal lines, wherein: the plurality of signal lines all extends along the first direction, orthographic projections of the plurality of signal lines on the substrate are first orthographic projections, orthographic projections of the first connection portion and the second connection portion on the substrate are second orthographic projections, and the second orthographic projection of at least one of the first connection portion and the second connection portion does not overlap with the first orthographic projections of the plurality of signal lines.

2. The display panel according to claim 1, wherein:
the plurality of signal lines is arranged at intervals along the second direction, and the second orthographic projection of at least one of the first connection portion and the second connection portion is located between two corresponding adjacent first orthographic projections of the plurality of signal lines.

3. The display panel according to claim 1, wherein:
the plurality of signal lines includes a first scanning signal line, wherein one pixel circuit includes a gate reset transistor and the first scanning signal line is electrically connected to a gate of the gate reset transistor;
the plurality of signal lines includes a first reference signal line, wherein the first orthographic projection of the first reference signal line is located on a side of the first orthographic projection of the first scanning signal line along the second direction, and the first reference signal line is electrically connected to a first electrode of the gate reset transistor; and
the plurality of signal lines includes a second scanning signal line, wherein the first orthographic projection of the second scanning signal line is located on a side of the first orthographic projection of the first scanning signal line away from the first orthographic projection of the first reference signal line, and the pixel circuit includes a write transistor wherein the second scanning signal line is electrically connected to a gate of the write transistor.

4. The display panel according to claim 3, wherein:
the second orthographic projection of at least one of the first connection portion and the second connection portion is located between the first orthographic projection of the corresponding first scanning signal line and the first orthographic projection of the first reference signal line.

5. The display panel according to claim 3, wherein:
the second orthographic projection of at least one of the first connection portion and the second connection portion is located between the corresponding first scanning signal line and the second scanning signal line.

6. The display panel according to claim 5, wherein:
the second orthographic projection of the first connection portion is located between the corresponding first scanning signal line and the second scanning signal line, the second orthographic projection of the first connection portion has a first distance from the first orthographic projection of the first scanning signal line along the second direction, and the second orthographic projection of the first connection portion has a second distance from the first orthographic projection of the second scanning signal line along the second direction, wherein the first distance is less than the second distance or the first distance is larger than the second distance; and/or
the second orthographic projection of the second connection portion is located between the corresponding first scanning signal line and the second scanning signal line, the second orthographic projection of the second connection portion has a third distance from the first orthographic projection of the first scanning signal line along the second direction, and the second orthographic projection of the second connection portion has a fourth distance from the first orthographic projection of the second scanning signal line along the second direction, wherein the third distance is smaller than the fourth distance or the third distance is larger than the fourth distance.

7. The display panel according to claim 3, wherein:
the second orthographic projection of at least one of the first connection portion and the second connection portion is located on a side of the first orthographic projection of the corresponding second scanning signal line away from the first orthographic projection of the first scanning signal line.

8. The display panel according to claim 3, wherein:
the plurality of signal lines includes a power signal line, wherein the first orthographic projection of the power signal line is located on a side of the first orthographic projection of the second scanning signal line away from the first orthographic projection of the first scanning signal line; and
the pixel circuit includes a first light-emitting transistor, wherein the power signal line is electrically connected to a first electrode of the first light-emitting transistor.

9. The display panel according to claim 8, wherein:
the second orthographic projection of at least one of the first connection portion and the second connection portion is located between the corresponding second scanning signal line and the power signal line.

10. The display panel according to claim 8, wherein:
the plurality of signal lines also includes a light-emitting control signal line, wherein: the first orthographic projection of the light-emitting control signal line is located on a side of the first orthographic projection of the power signal line away from the first orthographic projection of the second scanning signal line, the pixel circuit includes a second light-emitting transistor and a driving transistor, a second electrode of the first light-emitting transistor is electrically connected to a first electrode of the driving transistor, a second electrode of the driving transistor is electrically connected to a first electrode of the second light-emitting transistor, a gate of the driving transistor is electrically connected to a second electrode of the gate reset transistor, and the light-emitting control signal line is electrically connected to a gate of the first light-emitting transistor and a gate of the second light-emitting transistor; and
the plurality of signal lines also includes a second reference signal line, wherein: the first orthographic projection of the second reference signal line is located on a side of the first orthographic projection of the light-emitting control signal line away from the first orthographic projection of the power signal line; the pixel circuit includes an anode reset transistor, a gate of the anode reset transistor is electrically connected to the first scanning signal line, and a first electrode of the anode reset transistor is electrically connected to the second reference signal line.

11. The display panel according to claim 10, wherein:
the second orthographic projection of at least one of the first connection portion and the second connection portion is located between the corresponding second reference signal line and the light emission control signal line.

12. The display panel according to claim 3, wherein:
the write transistor includes a first write transistor and a second write transistor;
the pixel circuit includes a driving transistor;
the second scanning signal line is electrically connected to a gate of the first write transistor and a gate of the second write transistor;
a first electrode of the first write transistor is electrically connected to a first electrode of the driving transistor;
a second electrode of the driving transistor is electrically connected to a first electrode of the second write transistor;
a second electrode of the second write transistor is electrically connected to a gate of the driving transistor; and
in two adjacent pixel circuits in the second direction, the first data line is electrically connected to the second electrode of the first write transistor of one of the two adjacent pixel circuits through the first connection portion, and the second data line is electrically connected to the second electrode of the first write transistor of the other one of the two adjacent pixel circuits through the second connection portion.

13. The display panel according to claim 3, wherein:
a distance between the first orthographic projections and the second orthographic projections along the second direction is larger than or equal to 1 μm; and/or
a dimension of at least one of the first data line and the second data line along the first direction is less than or equal to 2.5 μm.

14. The display panel according to claim 3, wherein:
the first connection portion includes a first sub-connection portion and a second sub-connection portion, wherein the first sub-connection portion is located on a side of the second sub-connection portion away from the first data line and the first sub-connection portion is electrically connected to the corresponding pixel circuit through a first via hole;
a size of the first sub-connection portion along the second direction is larger than a size of the second sub-connection portion along the second direction; and
the size of the first sub-connection portion along the second direction is less than or equal to 8 μm; and/or the size of the second sub-connection portion along the second direction is less than or equal to 2.5 μm.

15. The display panel according to claim 3, wherein:
the second connection portion includes a third sub-connection portion and a fourth sub-connection portion, wherein the third sub-connection portion is located on a side of the fourth sub-connection portion away from the first data line and the third sub-connection portion is electrically connected to the corresponding pixel circuit through a second via hole;
a size of the third sub-connection portion along the second direction is larger than a size of the fourth sub-connection portion along the second direction; and
the size of the third sub-connection portion along the second direction is less than or equal to 8 μm; and/or the size of the fourth sub-connection portion along the second direction is less than or equal to 2.5 μm.

16. A display device comprising a display panel, wherein:
the display panel includes:
a substrate;
a plurality of pixel columns located on one side of the substrate, wherein the plurality of pixel columns are arranged along a first direction, one pixel column of the plurality of pixel columns includes a plurality of pixel circuits arranged along a second direction, and the first direction intersects with the second direction;
a first data line and a second data line, wherein: the first data line and the second data line extend along the second direction, a portion of pixel circuits in one pixel column of the plurality of pixel columns is electrically connected to the first data line and another portion of the pixel circuits in the pixel column is electrically connected to the second data line, a first connection portion is provided on a side of the first data line facing the second data line, and a second connection portion is provided on a side of the second data line facing the first data line; and
a plurality of signal lines, wherein: the plurality of signal lines all extends along the first direction, orthographic projections of the plurality of signal lines on the substrate are first orthographic projections, orthographic projections of the first connection portion and the second connection portion on the substrate are second orthographic projections, and the second orthographic projection of at least one of the first connection portion and the second connection portion does not overlap with the first orthographic projections of the plurality of signal lines.
